(19) United States
(12) Patent Application Publication
(10) Pub. No.: US 2019/0056824 A1
(43) Pub. Date: Feb. 21, 2019

(54) CONDUCTIVE SHEET FOR TOUCH SENSOR, LAMINATE FOR TOUCH SENSOR, TOUCH SENSOR, AND TOUCH PANEL

(71) Applicant: FUJIFILM Corporation, Tokyo (JP)

(72) Inventors: Akira ICHIKI, Kanagawa (JP); Keisho FUNATSU, Kanagawa (JP)

(73) Assignee: FUJIFILM Corporation, Tokyo (JP)

(21) Appl. No.: 16/166,669

(22) Filed: Oct. 22, 2018

Related U.S. Application Data
(63) Continuation of application No. PCT/JP2017/009199, filed on Mar. 8, 2017.

(30) Foreign Application Priority Data
Apr. 28, 2016 (JP) 2016-092063

(51) Int. Cl. G06F 3/044; H05K 1/09; H05K 1/02

(52) U.S. Cl. CPC G06F 3/044; H05K 1/09; H05K 1/028; H05K 2201/055; G06F 2203/04103; H05K 2201/10151; H05K 2201/0108; G06F 2203/04112

(57) ABSTRACT

A conductive sheet for a touch sensor includes a base material, a conductive portion that is disposed on the base material and is made of a fine metal wire, and a transparent insulation layer that is disposed on the conductive portion, in which the transparent insulation layer includes a crosslinking structure, and an indentation hardness of the transparent insulation layer is 200 MPa or less.

### CROSS-REFERENCE TO RELATED APPLICATIONS

This application is a Continuation of PCT International Application No. PCT/JP2017/009199, filed on Mar. 8, 2017, which claims priority under 35 U.S.C. § 119(a) to Japanese Patent Application No. 2016-092063, filed on Apr. 28, 2016. Each of the above application(s) is hereby expressly incorporated by reference, in its entirety, into the present application.

### BACKGROUND OF THE INVENTION

### 1. Field of the Invention

The present invention relates to a conductive sheet for a touch sensor, a laminate for a touch sensor, a touch sensor, and a touch panel.

### 2. Description of the Related Art

Recently, in a variety of electronic devices such as portable information devices, touch panels which are used in combination with a display device such as a liquid crystal display device and on which an input operation to an electronic device is carried out by touching a screen have been distributed.

Generally, a touch panel is manufactured by attaching individual members (a glass substrate, a conductive sheet for a touch sensor, a display device, and the like) through pressure-sensitive adhesive films such as optical clear adhesive (OCA) films.

Generally, the conductive sheet for a touch sensor has a conductive portion made of a pattern-like fine metal wire that serves as a detection electrode (sensor electrode) and a drawing wire (ambient electrode) on a base material.

At the present, there are cases in which a transparent insulation layer is formed as a protective film on the surface of the conductive portion of the conductive sheet for a touch sensor for the purpose of improving handleability or for the purpose of improving the abrasion resistance or solvent resistance of the conductive portion that serves as the detection electrode or the drawing wire.

For example, Paragraph 0056 of JP2015-524961A describes that a transparent protective layer that partially coats at least a first conductive layer and a second conductive layer that serve as the detection electrode and a first lead wire electrode and a second lead wire electrode that serve as the drawing wire may be installed during the production of a touch panel.

### SUMMARY OF THE INVENTION

Meanwhile, in recent years, the impartation of a three-dimensional shape to a touch panel has been proposed, and, at this time, a touch sensor is desirably bendable.

In addition, in association with the slimming of a bezel of a touch panel, it is desirable to dispose a region in which the drawing wire is disposed and a region which is connected to a flexible printed wiring board in a touch sensor on a rear surface of the touch sensor by bending the regions.

That is, conductive sheets applicable to touch sensors are desirably bendable.

Meanwhile, as a result of studies regarding a bending characteristic of the conductive sheet for a touch sensor including the transparent insulation layer as described in JP2015-524961A, there was a problem in that cracks were likely to be generated in the transparent insulation layer during the bending of the conductive sheet.

In addition, in a case in which the conductive sheet for a touch sensor including the transparent insulation layer was bent, and then the conductive sheet for a touch sensor was stored in a high-temperature and high-humidity environment, there was another problem in that fissuring and/or breakage occurred in the fine metal wire.

An object of the present invention is to provide a conductive sheet for a touch sensor in which cracks are not easily generated in a transparent insulation layer even in the case of being bent and fissuring and breakage do not easily occur in a fine metal wire even in the case of being left to stand in a high-temperature and high-humidity environment after being bent.

In addition, another object of the present invention is to provide a laminate for a touch panel, a touch sensor, and a touch panel which include the conductive sheet for a touch sensor.

As a result of intensive studies for achieving the above-described objects, the present inventors found that the above-described objects can be achieved by adjusting the characteristics of the transparent insulation layer and completed the present invention.

That is, it was found that the above-described object can be achieved by the following constitutions.

(1) A conductive sheet for a touch sensor comprising: a base material; a conductive portion that is disposed on the base material and is made of a fine metal wire; and a transparent insulation layer disposed on the conductive portion, in which the transparent insulation layer includes a crosslinking structure, and an indentation hardness of the transparent insulation layer is 200 MPa or less. (2) The conductive sheet for a touch sensor according to (1), in which a modulus of elasticity of the transparent insulation layer at 50° C. to 90° C. is 1×10⁵ Pa or more.

(3) The conductive sheet for a touch sensor according to (1) or (2), in which a modulus of elasticity of the transparent insulation layer at a temperature of 85° C. and a relative humidity of 85% is 1×10⁵ Pa or more.

(4) The conductive sheet for a touch sensor according to any one of (1) to (3), in which a difference between a linear expansion coefficient of the transparent insulation layer and a linear expansion coefficient of the base material is 300 ppm/° C. or less.

(5) The conductive sheet for a touch sensor according to any one of (1) to (4), in which the conductive portions are disposed on both surfaces of the base material, and the conductive portions include a mesh pattern made of a fine silver wire.

(6) The conductive sheet for a touch sensor according to any one of (1) to (5), further comprising: a main body portion; and a bending portion that is extended from the main body portion and is bendable.

(7) The conductive sheet for a touch sensor according to (6), further comprising: a curved portion that is formed by bending the bending portion.

(8) A laminate for a touch sensor comprising, in order: the conductive sheet for a touch sensor according to any one of (1) to (7); a pressure-sensitive adhesive sheet; and a peeling sheet.

(9) A touch sensor comprising: the conductive sheet for a touch sensor according to any one of (1) to (7).

(10) A touch panel comprising: the touch sensor according to (9).

According to the present invention, it is possible to provide a conductive sheet for a touch sensor in which cracks are not easily generated in a transparent insulation layer even in the case of being bent and fissuring and breakage do not easily occur in a fine metal wire even in the case of being left to stand in a high-temperature and high-humidity environment after being bent.

In addition, according to the present invention, it is possible to provide a laminate for a touch panel, a touch sensor, and a touch panel which include the conductive sheet for a touch sensor.

### BRIEF DESCRIPTION OF THE DRAWINGS

FIG. 1 is a partial cross-sectional view of a first embodiment of a conductive sheet for a touch sensor.

FIG. 2 is a partial plan view illustrating a shape of a mesh pattern.

FIG. 3 is a plan view of a second embodiment of the conductive sheet for a touch sensor.

FIG. 4 is a cross-sectional view cut along a cutting line IV-IV illustrated in FIG. 3.

FIG. 5 is an enlarged plan view of a first detection electrode.

FIG. 6 is a schematic diagram illustrating an aspect in which a bending portion of the conductive sheet for a touch sensor is curved.

FIG. 7 is a cross-sectional view of an electrostatic capacitance-type touch panel.

### DESCRIPTION OF THE PREFERRED EMBODIMENTS

Hereinafter, the present invention will be described in detail.

Constituent requirements described below will be described on the basis of a representative embodiment of the present invention in some cases, but the present invention is not limited to the above-described embodiment.

Meanwhile, in the present specification, numerical ranges expressed using “to” include numerical values before and after “to” as the lower limit value and the upper limit value.

In addition, “light” in the present specification, refers to an active light ray or a radiant ray. “Exposure to light” in the present specification refers not only to exposure to light such as a bright line spectrum of a mercury lamp, a far-ultraviolet ray represented by an excimer laser, X-rays, or EUV light but also to the exposure of a drawing to a particle ray such as an electron beam or an ion beam unless particularly otherwise described.

In addition, in the present specification, “(meth)acrylate” refers to any one or both of acrylate and methacrylate, and “(meth)acryl” refers to any one of both of acryl and methacryl.

In addition, “(meth)acryloyl” refers to any one or both of acryloyl and methacryloyl.

As characteristics of a conductive sheet for a touch sensor of the embodiment of the present invention, the introduction of a crosslinking structure into a transparent insulation layer and the adjustment of the indentation hardness of the transparent insulation layer to a predetermined range are exemplified.

The fissuring and breakage of a fine metal wire are assumed to be caused by stress generated depending on the bending form of the conductive sheet for a touch sensor including storage environment conditions. Therefore, it was found that the fissuring and breakage of a fine metal wire can be prevented by providing a transparent insulation layer having functions of relaxing the stress and reinforcing the strength of the fine metal wire on a surface of the fine metal wire. Specifically, in order to impart a function of reinforcing the strength to the transparent insulation layer, a crosslinking structure is introduced into the transparent insulation layer, thereby maintaining the superior stiffness of the transparent insulation layer. In addition, the indentation hardness of the transparent insulation layer is adjusted to a predetermined range so as to prevent cracks in the transparent insulation layer generated by bending from causing the breakage of the fine metal wire.

### First Embodiment

Hereinafter, a preferred aspect of the conductive sheet for a touch sensor of the embodiment of the present invention will be described with reference to drawings.

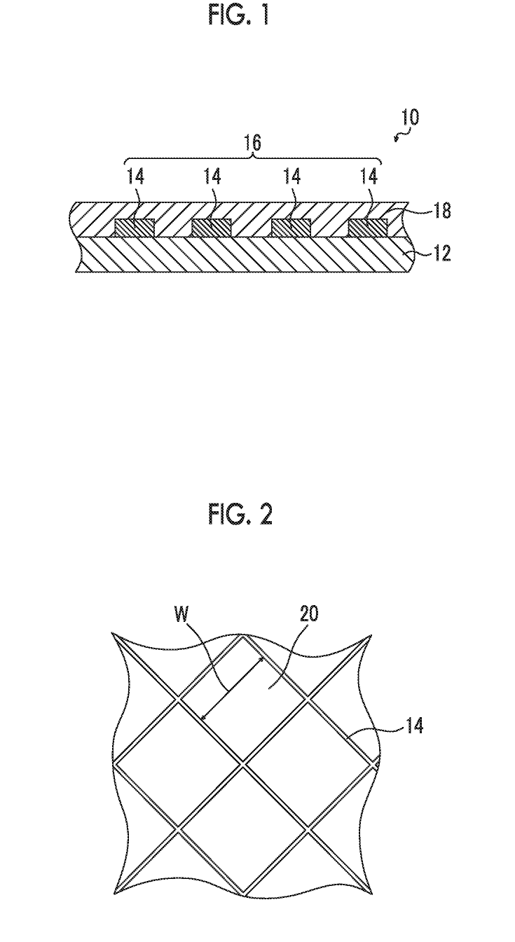

FIG. 1 illustrates a partial cross-sectional view of a first embodiment of a conductive sheet for a touch sensor 10 of the embodiment of the present invention. The conductive sheet for a touch sensor 10 comprises a base material 12, a conductive portion 16 that is disposed on the base material 12 and is made of a plurality of fine metal wires 14, and a transparent insulation layer 18 disposed on the conductive portion 16 (in other words, disposed so as to cover a surface of the base material 12 and the conductive portion 16).

Hereinafter, the respective members constituting the conductive sheet for a touch sensor will be described in detail.

<Base Material>

The kind of the base material is not limited as long as the base material is capable of supporting the conductive portion, but a transparent base material is preferred, and a plastic film is more preferred.

As a specific example of a material constituting the base material, a plastic film having a melting point of approximately 290° C. or lower such as polyethylene terephthalate (PET) (258° C.), polycycloolefin (134° C.), polycarbonate (250° C.), a (meth)acrylic resin (128° C.), polyethylene naphthalate (PEN) (269° C.), polyethylene (PE) (135° C.), polypropylene (PP) (163° C.), polystyrene (230° C.), polyvinyl chloride (180° C.), polyvinylidene chloride (212° C.), or triacetyl cellulose (TAC) (290° C.) is preferred, and a (meth)acrylic resin, PET, polycycloolefin, or polycarbonate is more preferred. Numerical values in the parentheses are melting points.

A total light transmittance of the base material is preferably 85% to 100%.

A thickness of the base material is not particularly limited and, generally, can be arbitrarily selected in a range of 25 to 500 μm from the viewpoint of the application to touch panels. Meanwhile, in the case of providing a function as a touching surface in addition to the functions of the base material, the base material can be designed in a thickness of more than 500 μm.

As another preferred aspect, the base material preferably has an undercoat layer including a polymer on the surface. The adhesiveness of the conductive portion is further improved by forming the conductive portion on the undercoat layer.

A method for forming the undercoat layer is not particularly limited, and examples thereof include a method in which a composition for forming the undercoat layer including a polymer is applied onto the base material and a heating treatment is carried out as necessary.

The composition for forming the undercoat layer may include a solvent as necessary. The kind of the solvent is not particularly limited, and well-known solvents are exemplified, in addition, as the composition for forming the undercoat layer, a latex including the fine particles of a polymer may also be used.

A thickness of the undercoat layer is not particularly limited, but is preferably 0.02 to 0.3 μm and more preferably 0.03 to 0.2 μm from the viewpoint of the adhesiveness of the conductive portion.

<Conductive Portion>

The conductive portion is disposed on the base material and is made of a plurality of fine metal wires. The conductive portion preferably constitutes mainly a detection electrode or a drawing wire in a touch sensor as described below.

A wire width of the fine metal wire is not particularly limited, but the upper limit is preferably 30 μm or less, more preferably 15 μm or less, still more preferably 10 μm or less, particularly preferably 9 μm or less, and most preferably 7 μm or less, and the lower limit is preferably 0.5 μm or more and more preferably 1.0 μm or more. In a case in which the wire width is in the above-described range, it is possible to relatively easily form an electrode having a low resistance.

In a case in which the fine metal wire is applied as a drawing wire, the wire width of the fine metal wire is preferably 500 μm or less, more preferably 50 μm or less, and still more preferably 30 μm or less. In a case in which the wire width is in the above-described range, it is possible to relatively easily form a touch panel electrode having a low resistance.

A thickness of the fine metal wire is not particularly limited, but is preferably 0.01 to 200 μm, more preferably 30 μm or less, still more preferably 20 μm or less, particularly preferably 0.01 to 9 μm, and most preferably 0.05 to 5 μm. In a case in which the thickness is in the above-described range, it is possible to relatively easily form an electrode having a low resistance and excellent durability.

A pattern of the conductive portion made of the fine metal wires is not particularly limited, but is preferably a triangle such as an equilateral triangle, an isosceles triangle, or a right triangle, a quadrangle such as a square, a rectangle, a rhomboid, a parallelogram, or a trapezoid, a (regular) polygon such as a (regular) hexagon or a (regular) octagon, or a geometric configuration obtained by combining a circle, an ellipse, a star shape, or the like, and more preferably a mesh shape formed of these geometric configurations.

The mesh shape refers to a shape including a plurality of opening portions (lattice) 20 constituted of the intersecting fine metal wires 14 as illustrated in FIG. 2.

The opening portion 20 is an open region surrounded by the fine metal wires 14. The upper limit of a length W of a side of the opening portion 20 is preferably 800 m or less, more preferably 600 μm or less, and still more preferably 400 μm or less, and the lower limit is preferably 5 μm or more, more preferably 30 μm or more, and still more preferably 80 μm or more.

From the viewpoint of the visible light transmittance, an opening ratio is preferably 85% or more, more preferably 90% or more, and still more preferably 95% or more. The opening ratio corresponds to a proportion of transmissive portions (the opening portions) in the conductive portion excluding the fine metal wires in the entire mesh shape.

Examples of a material of the fine metal wire include metals such as gold (Au), silver (Ag), copper (Cu), and aluminum (Al), alloys, and the like. Among these, silver is preferred since the conductive property of the fine metal wire is excellent.

The fine metal wire preferably includes a binder from the viewpoint of the adhesiveness between the fine metal wire and the base material.

As the binder, at least any resin selected from the group consisting of (meth)acrylic resins, styrene-based resins, vinyl-based resins, polyolefin-based resins, polyester-based resins, polyurethane-based resins, polyamide-based resins, polycarbonate-based resins, polydiene-based resins, epoxy-based resins, silicone-based resins, cellulose-based polymers, and chitosan-based polymers, a copolymer formed of a monomer constituting the above-described resins, or the like is exemplified since the adhesiveness between the fine metal wire and the base material is more favorable.

A method for manufacturing the fine metal wire is not particularly limited, and a well-known method can be employed. Examples thereof include a method in which a resist pattern is formed by exposing and developing a photoresist film on a metal foil formed on the surface of the base material and the metal foil exposed through the resist pattern is etched. In addition, a method in which paste including fine metal particles or a metal nanowire is printed on both main surfaces of the base material and metal plating is carried out on the paste is exemplified.

Furthermore, in addition to the above-described methods, a method in which silver halide is used is exemplified. More specifically, the method described in Paragraphs 0056 to 0114 of JP2014-209332A is exemplified.

As a preferred aspect of the conductive portion, an aspect including a mesh pattern formed of fine silver wires is exemplified, and the conductive portions are preferably disposed on both surfaces of the base material.

<Transparent Insulation Layer>

The transparent insulation layer is disposed so as to cover a surface (a region in which the conductive portion is not present) of the base material and the conductive portion. The transparent insulation layer has a function of protecting the conductive portion. Meanwhile, the transparent insulation layer may also be disposed so as to expose a part of the conductive portion (so as to leave a part of the conductive portion uncovered). However, as described below, the transparent insulation layer is preferably disposed in a portion of the conductive sheet for a touch sensor to be bent.

An indentation hardness of the transparent insulation layer is 200 MPa or less, preferably 150 MPa or less, and more preferably 130 MPa or less since the effects of the present invention is superior. The lower limit is not particularly limited, but is preferably 10 MPa or more. In a case in which the indentation hardness is 200 MPa or less, it is easy to obtain a desired effect.

The indentation hardness of the transparent insulation layer can be measured using a microhardness tester (PICODENT).

Meanwhile, in order for the transparent insulation layer to exhibit the above-described indentation hardness, a main chain structure of a resin constituting the transparent insulation layer is preferably a soft structure or preferably a structure in which a distance between crosslinking points is long.

A modulus of elasticity at 50° C. to 90° C. of the transparent insulation layer is preferably 1×10⁵ Pa or more and more preferably 1×10⁶ to 1×10¹⁰ MPa. In a case in which the base material thermally expands, the fine metal wires which are formed on the base material and have an expansion factor that is lower than that of the base material also extend in the same manner, which causes the breakage of the fine metal wires in some cases. In contrast, in a case in which the modulus of elasticity at 50° C. to 90° C. of the transparent insulation layer is in the above-described range, the transparent insulation layer is hard and does not easily extend even in the case of being used in a high-temperature and high-humidity environment in a state in which the conductive sheet for a touch sensor is bent, and thus the occurrence of the fissuring and breakage of the fine metal wires becomes difficult.

In addition, a modulus of elasticity at a temperature of 85° C. and a relative humidity of 85% of the transparent insulation layer is preferably 1×10⁵ Pa or more, more preferably 1×10⁶ Pa or more, and still more preferably 1.5×10⁶ Pa or more. The upper limit is not particularly limited, but is 1×10¹⁰ MPa in many cases. In a case in which the modulus of elasticity is in the above-described range, the occurrence of the fissuring and breakage of the fine metal wires becomes more difficult even in a case in which the transparent insulation layer is used in a high-temperature and high-humidity environment in a state in which the conductive sheet for a touch sensor is bent.

Meanwhile, the above-described elastic moduli of the transparent insulation layer can be measured using a microhardness tester (PICODENT) in a predetermined measurement environment (for example, a temperature of 85° C. and a relative humidity of 85%).

A linear expansion coefficient of the transparent insulation layer is not particularly limited, but is preferably 1 to 500 ppm/° C., more preferably 5 to 200 ppm/° C., and still more preferably 5 to 150 ppm/° C. In a case in which the linear expansion coefficient of the transparent insulation layer is in the above-described range, the occurrence of the fissuring and breakage of the fine metal wires becomes more difficult even in a case in which the transparent insulation layer is used in a high-temperature and high-humidity environment in a state in which the conductive sheet for a touch sensor is bent.

Meanwhile, the linear expansion coefficient of the transparent insulation layer can be computed using the following two expressions by measuring a curl value (the curvature radius of a curl) in the case of applying heat to a measurement specimen formed of the transparent insulation layer.

(linear expansion coefficient of transparent insulation layer−linear expansion coefficient of base material)×temperature difference=distortion of measurement specimen Expression 1:

distortion of measurement specimen={modulus of elasticity of base material×(thickness of base material)²}/{3×(1−Poisson's ratio of base material)×elastic modulus of transparent insulation layer×curvature radius of curl} Expression 2:

Meanwhile, since the breakage of the fine metal wires can be further suppressed, a difference between the linear expansion coefficient of the transparent insulation layer and the linear expansion coefficient of the base material is preferably small, and the upper limit of the difference is preferably 300 ppm/° C. or less and more preferably 150 ppm/° C. or less. The lower limit is not particularly limited, but 0 ppm/° C. can be exemplified.

A thickness of the transparent insulation layer is not particularly limited, however, in a case in which the thickness is large, cracks are likely to be generated in the transparent insulation layer in a case in which the conductive sheet for a touch sensor is bent. The thickness is preferably 1 to 20 μm and more preferably 5 to 15 μm since the adhesiveness of the conductive portion is superior and the film strength is superior while cracks are suppressed.

The transparent insulation layer has a property of transmitting light.

Meanwhile, a total light transmittance of the conductive sheet for a touch sensor including the transparent insulation layer is preferably 85% or more and more preferably 90% or more in the visible light range (wavelengths: 400 to 700 nm).

Meanwhile, the total light transmittance can be measured using a spectrophotometer CM-3600A (manufactured by Konica Minolta, Inc.).

Meanwhile, the total light transmittance of the transparent insulation layer is preferably adjusted so that the conductive sheet for a touch sensor exhibits the above-described total light transmittance and preferably at least 85% or more.

The transparent insulation layer preferably has an excellent adhesiveness to the conductive portion, and, specifically, the transparent insulation layer is preferably not peeled off in a tape adhesive force evaluation test using “610” manufactured by 3M.

In addition, the transparent insulation layer is in contact not only with the conductive portion but also with the region of the base material (or the undercoat layer or a binder layer) in which the conductive portion is not formed and thus preferably has an excellent adhesiveness to the base material (or the undercoat layer or the binder layer). Meanwhile, the binder layer refers to a layer that is disposed on the base material and between the fine metal wires and formed of a binder and is often formed in the case of manufacturing fine metal wires using a silver halide method.

In a case in which the adhesiveness between the transparent insulation layer and the base material and between the transparent insulation layer and the conductive portion is favorable, it is possible to further suppress the fissuring and breakage of the fine metal wires.

From the viewpoint of suppressing the surface reflection of the conductive sheet for a touch sensor, a refractive index difference between a refractive index of the transparent insulation layer and a refractive index of the base material is preferably small.

In addition, in a case in which a binder component is included in the fine metal wires of the conductive portion, a refractive index difference between the refractive index of the transparent insulation layer and a refractive index of the binder component is preferably small, and a resin component forming the transparent insulation layer and the binder component are more preferably the same material.

Meanwhile, as an example of the resin component forming the transparent insulation layer and the binder component being the same material, a case in which both the binder component and the resin component forming the transparent insulation layer are a (meth)acrylic resin can be exemplified.

Furthermore, in a case in which the conductive sheet for a touch sensor is applied to a touch panel as described above, there are cases in which a pressure-sensitive adhesive sheet (pressure-sensitive adhesive layer) is attached to the transparent insulation layer of the conductive sheet for a touch sensor. A refractive index difference between the refractive index of the transparent insulation layer and a refractive index of the pressure-sensitive adhesive sheet is preferably small in order to suppress light scattering in an interface between the transparent insulation layer and the pressure-sensitive adhesive sheet.

The transparent insulation layer includes a crosslinking structure. In a case in which the transparent insulation layer includes a crosslinking structure, the fine metal wires do not easily break even in a case in which the transparent insulation layer is used in a high-temperature and high-humidity environment in a state in which the conductive sheet for a touch sensor is bent.

In order to form a crosslinking structure, the transparent insulation layer is preferably formed using a polyfunctional compound as described below.

A material constituting the transparent insulation layer is not particularly limited as long as a layer exhibiting the above-described characteristics can be obtained.

Particularly, the transparent insulation layer is preferably a layer formed using a composition for forming a transparent insulation layer including a polymerizable compound having a polymerizable group since it is easy to control the characteristics of the transparent insulation layer.

Hereinafter, an aspect in which the composition for forming a transparent insulation layer is used will be described in detail.

(Method for Forming Transparent Insulation Layer)

A method for forming the transparent insulation layer using the composition for forming a transparent insulation layer is not particularly limited. Examples thereof include a method in which the composition for forming a transparent insulation layer is applied onto the base material and the conductive portion, and a curing treatment is carried out on a coated film as necessary, thereby forming the transparent insulation layer (coating method), a method in which the transparent insulation layer is formed on a temporary substrate and transferred to the surface of the conductive portion (transfer method), and the like. Among these, the coating method is preferred from the viewpoint of the ease of controlling the thickness.

In the case of the coating method, a method for applying the composition for forming a transparent insulation layer onto the base material and the conductive portion is not particularly limited, and well-known methods (for example, a coating method such as a gravure coater, a comma coater, a bar coater, a knife coater, a die coater, or a roll coater, an ink jet method, a screen printing method, and the like) can be used.

From the viewpoint of handleability and manufacturing efficiency, an aspect in which the composition for forming a transparent insulation layer is applied onto the base material and the conductive portion, and a drying treatment is carried out as necessary to remove a solvent, thereby forming a coated film is preferred.

Meanwhile, conditions of the drying treatment are not particularly limited; however, from the viewpoint of superior productivity, the drying treatment is preferably carried out at room temperature to 220° C. (preferably 50° C. to 120° C.) for one to 30 minutes (preferably one to 10 minutes).

From the viewpoint of productivity, furthermore, a status in which the composition for forming a transparent insulation layer does not include any solvent component and a drying step is not provided is preferred.

Meanwhile, in the case of the coating method, the curing treatment may be any of a photocuring treatment and a thermocuring treatment. Between these, the photocuring treatment is preferred from the viewpoint of alleviating damage to the base material and shortening a tack time.

An exposure method is not particularly limited, and examples thereof include a method in which the coated film is irradiated with an active light ray or a radiant ray. In the irradiation with an active light ray, an ultraviolet (UV) lamp, light irradiation with a visible light or the like, or the like is used. Examples of a light source include a mercury lamp, a metal halide lamp, a xenon lamp, a chemical lamp, a carbon arc lamp, and the like. In addition, as the radiant ray, an electron beam, an X-ray, an ion beam, a far-infrared ray, and the like are exemplified.

In the case of exposing the coated film, the polymerizable group included in the compound in the coated film is activated, crosslinking is formed between compounds, and the curing of the layer proceeds. An exposure energy needs to be approximately 10 to 8,000 mJ/cm² and preferably in a range of 50 to 3,000 mJ/cm².

The composition for forming a transparent insulation layer includes a polymerizable compound having a polymerizable group. The number of the polymerizable groups in the polymerizable compound is not particularly limited and may be one or plural. Among these, a polymerizable compound having two or more polymerizable groups is preferably used since a crosslinking structure can be formed in the transparent insulation layer.

The kind of the polymerizable group is not particularly limited, and examples thereof include radical polymerizable groups such as a (meth)acryloyl group, a vinyl group, and an allyl group, cationic polymerizable groups such as an epoxy group and an oxetane group, and the like. Among these, from the viewpoint of reactivity, radical polymerizable groups are preferred, and a (meth)acryloyl group is more preferred.

The polymerizable compound may be any form selected from a monomer, an oligomer, and a polymer. That is, the polymerizable compound may be an oligomer having a polymerizable group or a polymer having a polymerizable group.

Meanwhile, the monomer is preferably a compound having a molecular weight of less than 1,000.

In addition, the oligomer and the polymer are a polymer that is a combination of a limited number (generally 5 to 100) of monomers. The oligomer refers to a compound having a weight-average molecular weight of 3,000 or less, and the polymer refers to a compound having a weight-average molecular weight of more than 3,000.

One kind of the polymerizable compound may be used, or a plurality of kinds of the polymerizable compounds may be jointly used.

As a preferred aspect of the composition for forming a transparent insulation layer, an aspect including a polymerizable compound having two or more polymerizable groups (a polyfunctional compound) and at least one of a urethane (meth)acrylate compound or an epoxy (meth)acrylate compound can be exemplified.

Meanwhile, a urethane (meth)acrylate compound having two or more polymerizable groups corresponds to the above-described urethane (meth)acrylate compound, but is not the polyfunctional compound. In addition, an epoxy (meth)acrylate compound having two or more polymerizable groups corresponds to the above-described epoxy (meth)acrylate compound, but is not the polyfunctional compound.

The polyfunctional compound may be any compound having two or more polymerizable groups and is preferably a compound having two or more (meth)acryloyl groups.

Specifically, examples of difunctional (meth)acrylate include ethylene glycol di(meth)acrylate, diethylene glycol di(meth)acrylate, triethylene glycol di(meth)acrylate, tetraethylene glycol di(meth)acrylate, 1,4-butanediol di(meth)acrylate, 1,6-hexanediol di(meth)acrylate, 1,9-nonanediol di(meth)acrylate, glycerin di(meth)acrylate, neopentyl glycol di(meth)acrylate, 3-methyl-1,5 pentanediol di(meth)acrylate, 2-butyl-2-ethyl-1,3 propane di(meth)acrylate, dimethylol tricyclodecane di(meth)acrylate, propylene glycol di(meth)acrylate, dipropylene glycol di(meth)acrylate, tripropylene glycol di(meth)acrylate, tetrapropylene glycol di(meth)acrylate, neopentyl glycol hydroxypivalate di(meth)acrylate, 1,3 butanediol di(meth)acrylate, dimethylol dicyclopentane diacrylate, hexamethylene glycol diacrylate, hexaethylene glycol di(meth)acrylate, polyethylene glycol di(meth)acrylate, polypropylene glycol di(meth)acrylate, butylene glycol di(meth)acrylate, 2,2′-bis(4-acryloxydiethoxyphenyl)propane, biphenol A tetraethylene glycol diacrylate, and the like.

Examples of trifunctional (meth)acrylate include trimethylolpropane tri(meth)acrylate, ethylene oxide-modified trimethylolpropane tri(meth)acrylate, propylene oxide-modified trimethylolpropane tri(meth)acrylate, tris(acryloxyethyl) isocyanurate, caprolactone-modified tris(acryloxyethyl) isocyanurate, pentaerythritol tri(meth)acrylate, dipentaerythritol tri(meth)acrylate, alkyl-modified dipentaerythritol tri(meth)acrylate, tetramethylolmethane tri(meth)acrylate, ethylene oxide-modified glycerol triacrylate, propylene oxide-modified glycerol triacrylate, ε caprolactone-modified trimethylolpropane triacrylate, pentaerythritol triacrylate, and the like.

Examples of tetrafunctional (meth)acrylate include ditrimethylolpropane tetra(meth)acrylate, pentaerythritol ethoxy tetra(meth)acrylate, and pentaerythritol tetra(meth)acrylate.

Examples of pentafunctional (meth)acrylate include dipentaerythritol penta(meth)acrylate, alkyl-modified dipentaerythritol penta(meth)acrylate, dipentaerythritol hexa(meth)acrylate, caprolactone-modified dipentaerythritol hexa(meth)acrylate, polypentaerythritol polyacrylate, and the like.

A content of the polyfunctional compound in the composition for forming a transparent insulation layer is not particularly limited, but is preferably 0 to 50% by mass and more preferably 20 to 45% by mass of a total solid content of the composition for forming a transparent insulation layer since the effects of the present invention are superior.

Specifically, the urethane (meth)acrylate compound is preferably a compound that includes two or more photopolymerizable groups selected from the group consisting of an acryloyloxy group, an acryloyl group, a methacryloyloxy group, and a methacryloyl group in a molecule and includes one or more urethane bonds in a molecule. The above-described compound can be manufactured by, for example, a urethanization reaction between isocyanate and a hydroxyl group-containing (meth)acrylate compound. Meanwhile, the urethane (meth)acrylate compound may be a so-called oligomer or a polymer.

The photopolymerizable group is a polymerizable group that can be radical-polymerized. The polyfunctional urethane (meth)acrylate compound including two or more photopolymerizable groups in a molecule forms a transparent insulation layer having a high hardness and is thus useful.

The number of photopolymerizable groups in one molecule of the urethane (meth)acrylate compound is preferably at least two, for example, more preferably 2 to 10, and still more preferably 2 to 6. Meanwhile, two or more photopolymerizable groups included in the urethane (meth)acrylate compound may be the same as each other or different from each other.

The photopolymerizable group is preferably an acryloyloxy group or a methacryloyloxy group.

The number of urethane bonds included in a molecule of the urethane (meth)acrylate compound needs to be one or more and is preferably 2 or more and more preferably, for example, 2 to 5 since the hardness of a transparent insulation layer to be formed becomes higher.

Meanwhile, in the urethane (meth)acrylate compound including two urethane bonds in a molecule, the photopolymerizable groups may be bonded to only one urethane bond directly or through linking groups or may be bonded to two urethane bonds respectively directly or through linking groups.

In an aspect, one or more photopolymerizable groups are preferably bonded to each of the two urethane bonds that are bonded through linking groups.

As described above, in the urethane (meth)acrylate compound, the urethane bond and the photopolymerizable group may be bonded directly or a linking group may be present between the urethane bond and the photopolymerizable group. The linking group is not particularly limited, and linear or branched saturated or unsaturated hydrocarbon groups, cyclic groups, groups formed by combining two or more of the above-described groups, and the like can be exemplified. The number of carbon atoms in the hydrocarbon group is, for example, approximately 2 to 20, but is not particularly limited. In addition, examples of a cyclic structure included in the cyclic group include aliphatic rings (cyclohexane ring and the like), aromatic rings (benzene ring, naphthalene ring, and the like), and the like. The above-described groups may or may not have a substituent.

Meanwhile, in the present specification, unless particularly otherwise described, groups described may or may not have a substituent. In a case in which a given group has a substituent, as the substituent, an alkyl group (for example, an alkyl group having 1 to 6 carbon atoms), a hydroxy group, an alkoxyl group (for example, an alkoxyl group having 1 to 6 carbon atoms), a halogen atom (for example, a fluorine atom, a chlorine atom, or a bromine atom), a cyano group, an amino group, a nitro group, an acyl group, a carboxyl group, and the like can be exemplified.

The urethane (meth)acrylate compound can be synthesized using a well-known method. In addition, the urethane (meth)acrylate compound can also be procured from commercially available products.

Examples of a synthesis method include a method in which an alcohol, a polyol, and/or a hydroxy group-containing compound such as hydroxy group-containing (meth)acrylate and isocyanate are reacted with one another. In addition, a method in which a urethane compound obtained by the above-described reaction is esterified with (meth)acrylic acid as necessary can be exemplified. Meanwhile, the expression “(meth)acrylic acid” is used to indicate both acrylic acid and methacrylic acid.

As the isocyanate, for example, aromatic, aliphatic, and alicyclic polyisocyanates are exemplified, and examples thereof include tolylene diisocyanate, diphenylmethane diisocyanate, hydrogenated diphenylmethane diisocyanate, polyphenylmethane polyisocyanate, modified diphenylmethane diisocyanate, hydrogenated xylylene diisocyanate, xylylene diisocyanate, hexamethylene diisocyanate, trimethylhexamethylene diisocyanate, tetramethylxylylene diisocyanate, isophorone diisocyanate, norbornene diisocyanate, 1,3-bis(isocyanatomethyl) cyclohexane, phenylene diisocyanate, lysine diisocyanate, lysine triisocyanate, naphthalene diisocyanate, and the like. One kind of isocyanate may be used or two or more kinds of isocyanates may be jointly used.

Examples of the hydroxy group-containing (meth)acrylate include 2-hydroxyethyl acrylate, 2-hydroxypropyl acrylate, 2-hydroxybutyl acrylate, 4-hydroxybutyl acrylate, 2-hydroxyethyl acryloyl phosphate, 2-acryloyloxyethyl-2-hydroxypropyl phthalate, glycerin diacrylate, 2-hydroxy-3-acryloyloxypropyl acrylate, pentaerythritol triacrylate, dipentaerythritol pentaacrylate, caprolactone-modified 2-hydroxyethyl acrylate, cyclohexane dimethanol monoacrylate, and the like. One kind of hydroxy group-containing (meth)acrylate may be used or two or more kinds of hydroxy group-containing (meth)acrylates may be jointly used.

Commercially available products of the urethane (meth)acrylate compound are not limited to the following products, but examples thereof can include UA-306H, UA-306I, UA-306T, UA-510H. UF-8001G, UA-101I, UA-101T. AT-600, AH-600, and AI-600 manufactured by Kyoei Kagaku Kogyo, U-4HA, U-6HA, U-6LPA, UA-32P, U-15HA, and UA-1100H manufactured by Shin-Nakamura Chemical Co., Ltd., SHIKOH UV-1400B, SHIKOH UV-1700B. SHIKOH UV-6300B, SHIKOH UV-7550B, SHIKOH UV-7600B, SHIKOH UV-7605B, SHIKOH UV-7610B, SHIKOH UV-7620EA. SHIKOH UV-7630B, SHIKOH UV-7640B, SHIKOH UV-6630B, SHIKOH UV-7000B, SHIKOH UV-7510B, SHIKOH UV-7461TE, SHIKOH UV-3000B, SHIKOH UV-3200B, SHIKOH UV-3210EA, SHIKOH UV-3310EA, SHIKOH UV-3310B, SHIKOH UV-3500BA, SHIKOH UV-3520TL. SHIKOH UV-3700B, SHIKOH UV-6100B, SHIKOH UV-6640B, SHIKOH UV-2000B, SHIKOH UV-2010B, and SHIKOH UV-2250EA manufactured by The Nippon synthetic Chemical Industry Co., Ltd. In addition, SHIKOH UV-2750B manufactured by The Nippon synthetic Chemical Industry Co., Ltd., UL-503LN manufactured by Kyoei Kagaku Kogyo, UNIDIC 17-806, UNIDIC 17-813, UNIDIC V-4030, and UNIDIC V-4000BA manufactured by DIC Corporation, EB-1290K manufactured by Daicel UCB Co., Ltd., HIGH-COAP AU-2010 and HIGH-COAP AU-2020 manufactured by Tokushiki Co., Ltd., and the like.

Examples of hexa- or high-functional urethane (meth)acrylate compound can include ART RESIN UN-3320HA, ART RESIN UN-3320HC, ART RESIN UN-3320HS, and ART RESIN UN-904 manufactured by Negami Chemical Industrial Co., Ltd., SHIKOH UV-1700B, SHIKOH UV-7605B, SHIKOH UV-7610B, SHIKOH UV-7630B, and SHIKOH UV-7640B manufactured by The Nippon synthetic Chemical Industry Co., Ltd., NK OLIGO U-6PA, NK OLIGO U-10HA, NK OLIGO U-10PA, NK OLIGO U-1100H, NK OLIGO U-15HA, NK OLIGO U-53H, and NK OLIGO U-33H manufactured by Shin-Nakamura Chemical Co., Ltd., KRM8452, EBECRYL1290. KRM8200, EBECRYL5129, and KRM8904 manufactured by Daicel-Allnex Ltd. UX-5000 manufactured by Nippon Kayaku Co., Ltd., and the like.

In addition, as di to trifunctional urethane (meth)acrylate compound, NATOCO UV SELF-HEALING manufactured by Natoco & Co., Ltd., EXP DX-40 manufactured by DIC Corporation, and the like can also be exemplified.

A molecular weight (weight-average molecular weight Mw) of the urethane (meth)acrylate compound is preferably in a range of 300 to 10,000. In a case in which the molecular weight is in this range, it is possible to obtain a transparent insulation layer having an excellent flexibility and an excellent surface hardness.

In addition, the epoxy (meth)acrylate compound refers to a compound obtained by an addition reaction between polyglycidyl ether and (meth)acrylic acid and has at least two (meth)acryloyl groups in the molecule in many cases.

A total content of the urethane (meth)acrylate compound and the epoxy (meth)acrylate compound in the composition for forming a transparent insulation layer is not particularly limited, but is preferably 10 to 70% by mass and more preferably 30 to 65% by mass of the total solid content of the composition for forming a transparent insulation layer since the effect of the present invention is superior.

The composition for forming a transparent insulation layer may further include a monofunctional monomer and preferably includes monofunctional (meth)acrylate. A monofunctional monomer functions as a diluent monomer for controlling the crosslinking density in the transparent insulation layer.

Examples of the monofunctional (meth)acrylate include long-chain alkyl (meth)acrylate such as butyl (meth)acrylate, amyl (meth)acrylate, 2-ethylhexyl (meth)acrylate, octyl (meth)acrylate, nonyl (meth)acrylate, dodecyl (meth)acrylate, lauryl (meth)acrylate, hexadecyl (meth)acrylate, and octadecyl (meth)acrylate, (meth)acrylate having a cyclic structure such as cyclohexyl (meth)acrylate, benzyl (meth)acrylate, phenoxyethyl (meth)acrylate, nonylphenoxyethyl (meth)acrylate, tetrahydrofurfuryl (meth)acrylate, nonylphenoxyethyl tetrahydrofurfuyl (meth)acrylate, caprolactone-modified tetrafurfuryl (meth)acrylate, dicyclopentanyl (meth)acrylate, dicyclopentenyl (meth)acrylate, dicyclopentenyloxyethyl (meth)acrylate, ethylene oxide-modified nonylphenol (meth)acrylate, propylene oxide-modified nonylphenol (meth)acylate, and 2-ethylhexyl carbitol (meth)acrylate, glycidyl (meth)acrylate, methoxyethyl (meth)acrylate, butoxyethyl (meth)acrylate, 2-hydroxyethyl (meth)acrylate, 2-hydroxypropyl (meth)acrylate, 3-chloro-2-hydroxypropyl (meth)acrylate, dimethylaminoethyl (meth)acrylate, 2-(meth)acryloyloxyethyl acid phosphate, diethylaminoethyl (meth)acrylate, isomyristyl (meth)acrylate, isostearyl (meth)acrylate, 3-hydroxypropyl (meth)acrylate, 4-hydroxybutyl (meth)acrylate, isobornyl (meth)acrylate, esters of (meth)acrylic acid and a polyhydric alcohol, and the like.

A content of the monofunctional monomer in the composition for forming a transparent insulation layer is not particularly limited, but is preferably 0 to 40% by mass and more preferably 0 to 20% by mass of the total solid content of the composition for forming a transparent insulation layer since the effects of the present invention are superior.

The composition for forming a transparent insulation layer may further include a polymerization initiator. The polymerization initiator may be any of a photopolymerization initiator and a thermopolymerization initiator, but is preferably a photopolymerization initiator.

The kind of the photopolymerization initiator is not particularly limited, and well-known photopolymerization initiators (radical photopolymerization initiators and cationic photopolymerization initiators) can be used. Examples thereof include carbonyl compounds such as acetophenone, 2,2-diethoxyacetophenone, p-methylacetophenone, p-dimethylaminopropiophenone, benzophenone, 2-chlorobenzophenone, benzyl, benzoin, benzoin methyl ether, benzoin ethyl ether, benzoin isopropyl ether, 2,2-dimethoxy-1,2-diphenyl ethane-1-one, 1-cyclohexyl phenyl ketone, 1-hydroxycyclohexyl phenyl ketone, 2-hydroxy-2-methyl-1-phenylpropane-1-one, 1-[4-(2-hydroxyethoxy)-phenyl]-2-hydroxy-2-methyl-1-propane-1-one, oligo(2-hydroxy-2-methyl-1-(4-(1-methylvinyl)phenyl)propanone), 2-hydroxy-1-{4-[4-(2-hydroxy-2-methyl-propionyl)-benzyl]-phenyl}-2-methylpropane-1-one, 2-methyl-1-[4-(methylthio)phenyl]-2-morpholinopropane-1-one, 2-benzyl-2-dimethylamino-1-(4-morpholinophenyl)-butanone-1, bis(2,4,6-trimethylbenzoyl)-phenylphosphine oxide, 2,4,6-trimethylbenzoyl-diphenylphosphine oxide, bis(2,6-dimethoxybenzoyl)-2,4,4-trimethyl-pentylphosphine oxide, ethyl-(2,4,6-trimethylbenzoyl)phenylphosphinate, 1,2-octanedione, 1-[4-(phenylthio)-,2-(O-benzoyloxime)], methylbenzoyl formate, 4-methylbenzophenone, 4-phenylbenzophenone, 2,4,6-trimethylbenzophenone, 4-benzoyl-4′-methyldiphenyl sulfide, and 1-[4-(4-benzoylphenylsulfanyl)phenyl]-2-methyl-2-(4-methylphenylsulfonyl)propane-1-one, sulfur compounds such as thioxanthone, 2-chlorothioxanthone, 2-methylthioxanthone, tetramethylthiuram disulfide, and the like.

One kind of polymerization initiator can be used singly or two or more kinds of polymerization initiators can be used in combination.

A content of the polymerization initiator in the composition for forming a transparent insulation layer is not particularly limited, but is preferably 0.1 to 10% by mass and more preferably 2 to 5% by mass of the total solid content of the composition for forming a transparent insulation layer from the viewpoint of the curing property. Meanwhile, in a case in which two or more kinds of polymerization initiators are used, the total content of the polymerization initiators is preferably in the above-described range.

To the composition for forming a transparent insulation layer, in addition to the above-described components, a variety of well-known additives of the related art such as a leveling agent, a surface lubricant, an antioxidant, a corrosion inhibitor, a light stabilizer, an ultraviolet absorbent, a polymerization inhibitor, a silane coupling agent, an inorganic or organic filler, powder such as metal powder and a pigment, and a particle-like or foil-like substance can be appropriately added depending on the intended use. Regarding the details thereof, it is possible to refer to, for example, Paragraphs 0032 to 0034 of JP2012-229412A. However, the additives are not limited thereto, and a variety of additives that can be generally used for photopolymerizable compositions can be used. In addition, an amount of the additives added to the composition for forming a transparent insulation layer may be appropriately adjusted and is not particularly limited.

As the leveling agent, well-known leveling agents can be used as long as the leveling agents have an action of imparting wettability to a coating subject of the composition for forming a transparent insulation layer and an action of decreasing surface tension. Examples thereof include a silicone-modified resin, a fluorine-modified resin, an alkyl-modified resin, and the like.

Meanwhile, the composition for forming a transparent insulation layer may include a solvent from the viewpoint of handleability, and the solvent is preferably an inorganic solvent from the viewpoint of suppressing volatile organic compounds (VOC) and the viewpoint of decreasing the tack time.

Meanwhile, in a case in which the composition for forming a transparent insulation layer contains a solvent, the solvent being used is not particularly limited, and examples thereof include water and organic solvents.

The first embodiment of the conductive sheet for a touch sensor has been described in detail in FIG. 1, but a constitution of the conductive sheet for a touch sensor is not limited to this aspect.

In FIG. 1, the conductive sheet for a touch sensor having the conductive portion 16 and the transparent insulation layer 18 disposed on only one surface of the base material 12 has been described, but the conductive sheet for a touch sensor of the embodiment of the present invention may have the conductive portions 16 and the transparent insulation layers 18 disposed on both surfaces of the base material 12.

In the conductive sheet for a touch sensor of the embodiment of the present invention, the transparent insulation layer has a predetermined indentation hardness, and thus the conductive sheet for a touch sensor can be used in a state of being bent at a predetermined location.

Meanwhile, as described below, in a case in which a bending portion is included in the conductive sheet for a touch sensor, the transparent insulation layer is preferably disposed so as to cover the fine metal wires included in the bending portion. That is, the transparent insulation layer is preferably disposed on the conductive portion located in a bent region of the conductive sheet for a touch sensor.

### Second Embodiment

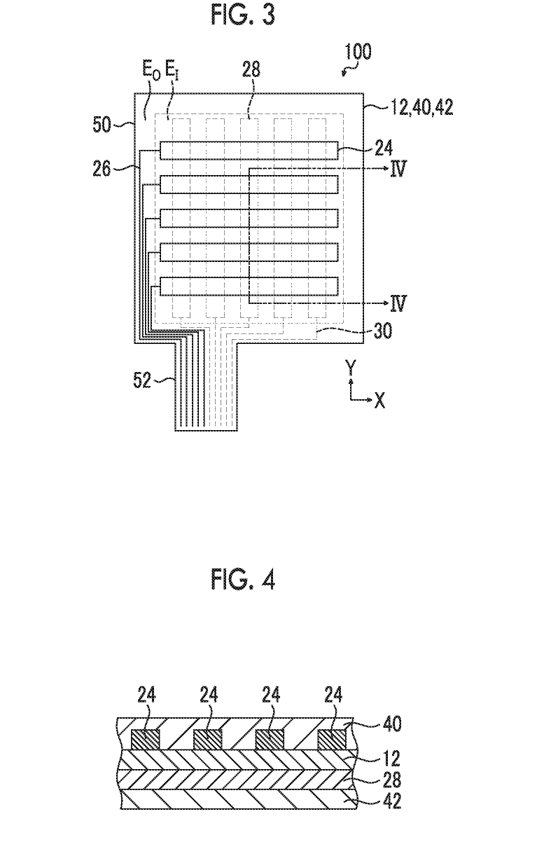

In FIG. 3, a second embodiment of the conductive sheet for a touch sensor is described in detail.

FIG. 3 illustrates a plan view of a conductive sheet for a touch sensor 100. FIG. 4 is a cross-sectional view cut along a cutting line IV-IV illustrated in FIG. 3. The conductive sheet for a touch sensor 100 comprises the base material 12, a plurality of first detection electrodes 24 disposed on one main surface (on a front surface) of the base material 12, a plurality of first drawing wires 26, a plurality of second detection electrodes 28 disposed on the other main surface (on a rear surface) of the base material 12, a plurality of second drawing wires 30, a first transparent insulation layer 40 disposed so as to cover the first detection electrodes 24 and the first drawing wires 26, and a second transparent insulation layer 42 disposed so as to cover the second detection electrodes 28 and the second drawing wires 30.

Meanwhile, as described below, the first detection electrodes 24 and the second detection electrodes 28 are constituted of fine metal wires.

Regions in which the first detection electrodes 24 and the second detection electrodes 28 constitute an input region E_{I} (an input region capable of detecting the contact of an article (sensing portion)) in which an input operation can be carried out by a user, and, in an outside region E_{O} located outside the input region E_{I}, the first drawing wires 26 and the second drawing wires 30 are disposed.

The conductive sheet for a touch sensor 100 has a main body portion 50 and a bending portion 52 that is extended from the main body portion 50 and is bendable. In a vicinity of an end portion of the bending portion 52, one end portion of each of the first drawing wires 26 and the second drawing wires 30 is located and can be electrically connected to a flexible printed wiring board.

Meanwhile, the base material 12 of the conductive sheet for a touch sensor 100 corresponds to the above-described base material, the first detection electrodes 24, the first drawing wires 26, the second detection electrodes 28, and the second drawing wires 30 of the conductive sheet for a touch sensor 100 correspond to the above-described conductive portion, and the first transparent insulation layer 40 and the second transparent insulation layer 42 of the conductive sheet for a touch sensor 100 correspond to the above-described transparent insulation layer.

Hereinafter, the above-described constitution will be described in detail.

The base material 12 is a member that plays a role of supporting the first detection electrodes 24 and the second detection electrodes 28 in the input region E_{I} and plays a role of supporting the first drawing wires 26 and the second drawing wires 30 in the output region E_{O}.

The definition and the preferred aspect of the base material 12 are as described above.

The first detection electrodes 24 and the second detection electrodes 28 are sensing electrodes that detect a change in the electrostatic capacitance and constitute a sensing portion (sensor portion). That is, in a case in which a fingertip comes into contact with a touch panel, the mutual electrostatic capacitance between the first detection electrode 24 and the second detection electrode 28 changes, and the location of the fingertip is computed using an IC circuit (integrated circuit) on the basis of this change amount.

The first detection electrode 24 plays a role of detecting an input location in an X direction of a user's finger that has come close to the input region E_{I} and has a function of generating an electrostatic capacitance between the finger and the first detection electrode. The first detection electrodes 24 are electrodes that extend in a first direction (X direction) and are arrayed in a second direction (Y direction) orthogonal to the first direction at predetermined intervals and have a predetermined pattern as described below.

The second detection electrode 28 plays a role of detecting an input location in a Y direction of the user's finger that has come close to the input region E₁ and has a function of generating an electrostatic capacitance between the finger and the second detection electrode. The second detection electrodes 28 are electrodes that extend in the second direction (Y direction) and are arrayed in the first direction (X direction) at predetermined intervals and have a predetermined pattern as described below. In FIG. 3, the number of the first detection electrodes 24 provided is five, and the number of the second detection electrodes 28 provided is also five, but the numbers are not particularly limited, but need to be plural.

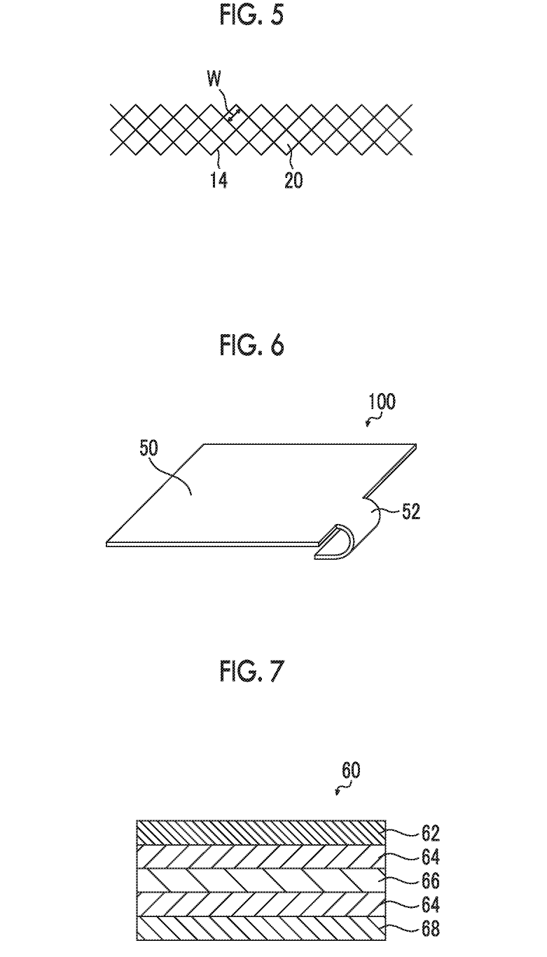

In FIG. 3, the first detection electrodes 24 and the second detection electrodes 28 are constituted of fine metal wires. FIG. 5 is an enlarged plan view of a part of the first detection electrode 24. As illustrated in FIG. 5, the first detection electrode 24 is constituted of the fine metal wires 14 and includes a plurality of opening portions 20 formed by the intersecting fine metal wires 14. Meanwhile, the second detection electrode 28 also, similar to the first detection electrode 24, includes a plurality of opening portions 20 formed by the intersecting fine metal wires 14. That is, the first detection electrodes 24 and the second detection electrodes 28 correspond to the conductive portion having a mesh pattern formed of a plurality of the above-described fine metal wires.

The first detection electrodes 24 and the second detection electrodes 28 correspond to the above-described conductive portion and has a mesh pattern formed of a plurality of fine metal wires. The definition and the preferred aspect of the fine metal wires constituting the first detection electrodes 24 and the second detection electrodes 28 are as described above.

In addition, the definition (for example, a length W of a side) of an opening portion 36 is also as described above.

Each of the first drawing wires 26 and the second drawing wires 30 is a member playing a role of applying voltage to the first detection electrodes 24 and the second detection electrodes 28.

The first drawing wires 26 are disposed on the base material 12 in the output region E_{O}, and one end of the first drawing wire is electrically connected to the corresponding first detection electrode 24, and the other end thereof is electrically connected to a flexible printed wiring board.

The second drawing wires 30 are disposed on the base material 12 in the output region E_{O}, and one end of the second drawing wire is electrically connected to the corresponding second detection electrode 28, and the other end thereof is electrically connected to a flexible printed wiring board.

Meanwhile, In FIG. 3, the number of the first drawing wires 26 illustrated is five, and the number of the second drawing wires 30 illustrated is also five, but the numbers are not particularly limited, and, generally, a plurality of drawing wires is disposed depending on the number of the detection electrodes.

The first transparent insulation layer 40 is a layer disposed on the base material 12 so as to cover the first detection electrodes 24 and the first drawing wires 26. In addition, the second transparent insulation layer 42 is a layer disposed on the base material 12 so as to cover the second detection electrodes 28 and the second drawing wires 30.

The definitions of the first transparent insulation layer 40 and the second transparent insulation layer 42 are as described above.

Meanwhile, the first transparent insulation layer 40 and the second transparent insulation layer 42 are disposed on the base material 12 in a region other than a region in which the above-described flexible printed wiring board 32 is disposed.

Meanwhile, in FIG. 5, the first transparent insulation layer 40 and the second transparent insulation layer 42 are disposed so as to be located in both the input region E_{I} and the output region E_{O}, but both layers may be disposed only in one region, and a separate transparent insulation layer may be disposed in the other region. For example, the first transparent insulation layer 40 and the second transparent insulation layer 42 may be disposed only on the drawing wires located in the bending portion 52.

Meanwhile, since the transparent insulation layers can be formed with a single time of a coating step, the same transparent insulation layer is preferably disposed in both the input region E_{I} and the output region E_{O}.

As illustrated in FIG. 6, the bending portion 52 can be bent so that one end thereof is located on a rear surface of the main body portion 50 of the conductive sheet for a touch sensor 100. In FIG. 6, one end of the bending portion 52 is located on the rear surface of the main body portion 50, and the flexible printed wiring board, not illustrated, is electrically connected to end portions of the drawing wires disposed on the one end portion of the bending portion. In a case in which a curved portion bent in the above-described bending portion is formed, the space saving of a touch sensor is achieved. That is, in a case in which the conductive sheet for a touch sensor having the above-described transparent insulation layers is used, a conductive sheet for a touch sensor having a curved structure can be obtained.

In FIG. 6, the conductive sheet for a touch sensor in which the bending portion 52 is extended from one end of the main body portion 50 has been described, but the present invention is not limited to this aspect, and the conductive sheet for a touch sensor may include a plurality of bending portions.

For example, in FIG. 3, the drawing wires (the first drawing wires 26 and the second drawing wires 30) from both surfaces of the base material 12 are commonly disposed in the bending portion 52, but the first drawing wires 26 and the second drawing wires 30 may be respectively disposed in two bending portions separately extended from different sides of the base material 12 respectively. In this case, the extended bending portions are present at two places.

In addition, there are cases in which a portion connected to the flexible printed wiring board is divided into a plurality of places depending on portions on the screen in association of the enlargement of the size of the input region. In this case, the number of portions corresponding to the bending portion becomes the number of portions to be connected to the flexible printed wiring board and may be three or more.

In addition, FIG. 6 illustrates an aspect in which the bending portion has the base material, the drawing wires disposed on the base material, and the transparent insulation layers disposed on the drawing wires, but the constitution is not limited thereto as long as the above-described conductive portion and the above-described transparent insulation layer are included.

[Touch Panel]

The conductive sheet for a touch sensor is preferably applied to a touch panel. In a case in which the conductive sheet for a touch sensor is applied to a touch panel, the conductive sheet for a touch sensor functions as a part of a touch sensor (touch panel sensor).

More specifically, as a preferred aspect of an electrostatic capacitance-type touch panel including the conductive sheet for a touch sensor, an electrostatic capacitance-type touch panel 60 comprises a protective substrate 62, a pressure-sensitive adhesive sheet 64, an electrostatic capacitance-type touch sensor 66, a pressure-sensitive adhesive sheet 64, and a display device 68 as illustrated in FIG. 7.

Hereinafter, a variety of members that are used in the electrostatic capacitance-type touch panel 60 will be described in detail.

Meanwhile, in the following description, the electrostatic capacitance-type touch panel will be described, but the conductive sheet for a touch sensor of the embodiment of the present invention may also be applied to different types of touch panels.

(Protective Substrate)

The protective substrate is a substrate disposed on the pressure-sensitive adhesive sheet and plays a role of protecting an electrostatic capacitance-type touch sensor described below from the outside environment, and a main surface thereof constitutes a touch surface.

The protective substrate is preferably a transparent substrate, and a plastic film, a plastic plate, a glass plate, or the like is used. A thickness of the substrate is desirably appropriately selected depending on individual uses.

As a raw material of the plastic film and the plastic plate, for example, polyesters such as polyethylene terephthalate (PET) and polyethylene naphthalate (PEN); polyolefins such as polyethylene (PE), polypropylene (PP), polystyrene, and polyethylene vinyl acetate copolymer (EVA); vinyl-based resins; additionally, polycarbonate (PC), polyamide, polyimide, acrylic resins, triacetyl cellulose (TAC), cycloolefin-based resins (COP), and the like can be used.

In addition, as the protective substrate, a polarizing plate, a circularly polarizing plate, or the like may also be used.

(Pressure-Sensitive Adhesive Sheet)

The pressure-sensitive adhesive sheet (pressure-sensitive adhesive layer) is disposed in order to attach the electrostatic capacitance-type touch sensor and the protective substrate or the display device. The pressure-sensitive adhesive sheet (pressure-sensitive adhesive layer) is not particularly limited, and well-known pressure-sensitive adhesive sheets can be used.

(Electrostatic Capacitance-Type Touch Sensor)

The electrostatic capacitance-type touch sensor is a sensor formed using the above-described conductive sheet for a touch sensor. More specifically, the electrostatic capacitance-type touch sensor can be formed by connecting a flexible printed wiring board to a conductive sheet for a touch sensor as illustrated in FIG. 3.

(Display Device)

The display device is a device having a display surface that displays images, and the respective members are disposed on a display screen side.

The kind of the display device is not particularly limited, and well-known display devices can be used. Examples thereof include a cathode ray tube (CRT) display device, a liquid crystal display device (LCD), an organic light-emitting diode (OLED) display device, a vacuum fluorescent display (VFD), a plasma display panel (PDP), a surface electric field display (SED), a field emission display (FED), electronic paper (E-paper), and the like.

Hitherto, an example of the touch panel in which the conductive sheet for a touch sensor of the embodiment of the present invention is caused to function as a part of the touch sensor has been described.

Meanwhile, the touch panel in which the conductive sheet for a touch sensor of the embodiment of the present invention may also be used in a form of a laminate for a touch panel having a conductive sheet for a touch sensor, a pressure-sensitive adhesive sheet, and a peeling sheet in this order while being handled and transported. The peeling sheet functions as a protective sheet for preventing the conductive sheet for a touch sensor from being damaged while the touch panel laminate is transported. In the case of the above-described aspect, the laminate for a touch panel can be attached to a predetermined location and used by peeling off the peeling sheet during use.

In addition, the conductive sheet for a touch sensor of the embodiment of the present invention may also be handled in a form of, for example, a complex having a conductive sheet for a touch sensor, a pressure-sensitive adhesive sheet, and a protective substrate in this order Examples

Hereinafter, the present invention will be described in more detail on the basis of examples. Materials, amounts used, proportions, treatment contents, treatment orders, and the like described in the following examples can be appropriately modified within the scope of the gist of the present invention. Therefore, the scope of the present invention is not supposed to be restrictively interpreted by the examples described below.

### Example 11

<<Production of Conductive Sheet for Touch Sensor>>

<Formation of Conductive Portion>

(Preparation of Silver Halide Emulsion)

90% of a liquid 2 described below and 90% of a liquid 3 described below were added at the same time to a liquid 1 described below held at 38° C. and a pH of 4.5 for 20 minutes under stirring, thereby forming 0.16 μm nucleus particles. Subsequently, a liquid 4 described below and a liquid 5 described below were added thereto for eight minutes, and, furthermore, the remaining 10% of the liquid 2 described below and the remaining 10% of the liquid 3 described below were added thereto for two minutes, thereby causing the particles to grow up to 0.21 μm. Furthermore, 0.15 g of potassium iodide was added thereto, the particles were aged for five minutes, and the formation of the particles was finished.

Liquid 1:

| | | |
|---|---|---|
| Water | 750 | ml |
| Gelatin | 8.6 | g |
| Sodium chloride | 3 | g |
| 1,3-dimethylimidazolidine-2-thione | 20 | mg |
| Sodium benzene thiosulfonate | 10 | mg |
| Citric acid | 0.7 | g |

Liquid 2:

| | |
|---|---|
| Water | 300 ml |
| Silver nitrate | 150 g |

Liquid 3:

| | | |
|---|---|---|
| Water | 300 | ml |
| Sodium chloride | 38 | g |
| Potassium bromide | 32 | g |
| Potassium hexachloroiridate (III) | 5 | ml |
| (0.005% KCl 20% aqueous solution) | | |
| Ammonium hexachlororhodiumate | 7 | ml |
| (0.001% NaCl 20% aqueous solution) | | |

Liquid 4:

| | |
|---|---|
| Water | 100 ml |
| Silver nitrate | 50 g |

Liquid 5:

| | | |
|---|---|---|
| Water | 100 | ml |
| Sodium chloride | 13 | g |
| Potassium bromide | 11 | g |
| Yellow prussiate of potash | 5 | mg |

After that, the particles were pickled using a flocculation method according to a normal method. Specifically, a temperature of a solution obtained above was decreased to 35° C., and a pH was decreased using sulfuric acid until silver halide settled (the pH was in a range of 3.6±0.2). Next, approximately 3 liters of a supernatant liquid was removed (first pickling). Furthermore, 3 liters of distilled water was added thereto, and thus sulfuric acid was added thereto until silver halide settled. Again, approximately 3 liters of a supernatant liquid was removed (second pickling). The same operation as the second pickling was further repeated once (third pickling), and a pickling and desalination step was finished. A pickled and desalinated emulsion was adjusted to a pH of 6.4 and a pAg of 7.5, 2.5 g of gelatin, 10 mg of sodium benzene thiosulfonate, 3 mg of sodium benzene thiosulfinate, 15 mg of sodium thiosulfate, and 10 mg of chlorauric acid were added thereto, and chemical sensitization was carried out so as to obtain the optimal sensitivity at 55° C. After that, furthermore, 100 mg of 1,3,3a,7-tetraazaindene as a stabilizer and 100 mg of PROXEL (trade name, manufactured by ICI Co., Ltd.) as a preservative were added thereto. A finally-obtained emulsion was an silver iodochlorobromide cubic particle emulsion which included 0.08 mol % of silver iodide, has a ratio between silver chloride and silver bromide in silver chlorobromide of 70 mol % and 30 mol %, an average particle diameter of 0.22 μm, and a coefficient of variation of 9%.

(Preparation of Composition for Forming Photosensitive Layer)

1.2×10⁴ mol/mol Ag of 1,3,3a,7-tetraazaindene, 1.2×10⁻² mol/mol Ag of hydroquinone, 3.0×10⁻⁴ mol/mol Ag of citric acid, 0.90 μg/mol Ag of 2,4-dichloro-6-hydroxy-1,3,5-triazine sodium salt, and a small amount of a hardener were added to the above-described emulsion, and a pH of a coating fluid was adjusted to 5.6 using citric acid.

In the above-described coating fluid, a polymer latex containing a polymer represented by Formula (P-1) and a dispersant made of dialkyl phenyl polyethylene glycol (PEO) sulfuric acid ester (a mass ratio of the dispersant to the polymer was 2.0/100=0.02) was added to the gelatin contained in the coating fluid so that a mass ratio of the polymer to the gelatin reached 0.5/1.

Furthermore, EPOXY RESIN DY 022 (trade name, manufactured by Nagase ChemteX Corporation) was added thereto as a crosslinking agent. Meanwhile, an amount of the crosslinking agent added was adjusted so that an amount of the crosslinking agent in a silver halide-containing photosensitive layer described below reached 0.09 g/m².

A composition for forming a photosensitive layer was prepared as described above.

Meanwhile, the polymer represented by Formula (P-1) was synthesized with reference to JP3305459B and JP3754745B.

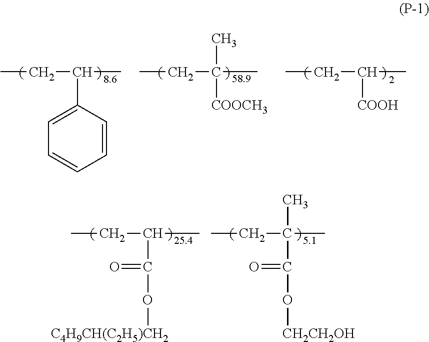

(Photosensitive Layer-Forming Step)

The above-described polymer latex was applied onto a 100 μm-thick polyethylene terephthalate (PET) film (linear expansion coefficient: 20 ppm/° C.), thereby providing a 0.05 μm-thick undercoat layer.

Next, a silver halide-free composition for forming a layer in which the polymer latex and gelatin were mixed together was applied onto the undercoat layer, thereby providing a 1.0 μm-thick silver halide-free layer. Meanwhile, a mixing mass ratio (polymer/gelatin) of the polymer to gelatin was 2/1, and a content of the polymer was 0.65 g/m².

Next, the composition for forming a photosensitive layer was applied onto the silver halide-free layer, thereby providing a 2.5 μm-thick silver halide-containing photosensitive layer. Meanwhile, a mixing mass ratio (polymer/gelatin) of the polymer to gelatin in the silver halide-containing photosensitive layer was 0.5/1, and a content of the polymer was 0.22 g/m².

Next, a composition for forming a protective layer in which the polymer latex and gelatin were mixed together was applied onto the silver halide-containing photosensitive layer, thereby providing a 0.15 μm-thick protective layer. Meanwhile, a mixing mass ratio (polymer/gelatin) of the polymer to gelatin was 0.1/1, and a content of the polymer was 0.015 g/m².

(Exposure and Development Treatment)

The photosensitive layer produced above was exposed using parallel light coming from a high-pressure mercury lamp as a light source through a photomask capable of imparting a developed silver image having a pattern of line/space=30 μm/30 μm (the number of lines was 20). After the exposure, the photosensitive layer was developed with a developer described below, furthermore, subjected to a development treatment using a fixer (trade name: N3X-R for CN16X, manufactured by Fujifilm Corporation), rinsed with pure water, and then dried.

(Composition of Developer)

1 liter (L) of the developer included compounds described below.

| | |
|---|---|
| Hydroquinone | 0.037 mol/L |
| N-methylaminophenol | 0.016 mol/L |
| Sodium metaborate | 0.140 mol/L |
| Sodium hydroxide | 0.360 mol/L |
| Sodium bromide | 0.031 mol/L |
| Potassium metabisulfite | 0.187 mol/L |

(Heating Treatment)

Furthermore, the photosensitive layer was left to stand in an overheated steam vessel (120° C.) for 130 seconds, thereby carrying out a heating treatment.

(Gelatin Decomposition Treatment)

Furthermore, the photosensitive layer was immersed in a gelatin decomposition fluid (40° C.) prepared as described below for 120 seconds and then immersed in warm water (liquid temperature: 50° C.) for 120 seconds, thereby washing the photosensitive layer.

Preparation of Gelatin Decomposition Fluid:

Triethanolamine and sulfuric acid were added to an aqueous solution of a protein degrading enzyme (BIOPLASE 30L manufactured by Nagase & Co., Ltd.) (a concentration of the protein degrading enzyme: 0.5% by mass), and a pH was adjusted to 8.5.

(Polymer Crosslinking Treatment)

Furthermore, the photosensitive layer was immersed in a 1% aqueous solution of CARBODILITE V-02-L2 (trade name: manufactured by Nisshinbo Chemical Inc.) for 30 seconds, removed from the aqueous solution, immersed in pure water (at room temperature) for 60 seconds, and washed.

A film A in which a conductive portion made of a fine silver wiring pattern was formed on the PET film was obtained in the above-described manner.

<Formation of Transparent Insulation Layer>

A liquid mixture of 30 wt % of (pentaerythritol (tri/tetra)acrylate (PETA) (trade name: KAYARAD PET-30) manufactured by Nippon Kayaku Co., Ltd.) as a tri- or higher-functional polyfunctional compound, 36.9 wt % of NATOCO UV SELF-HEALING (manufactured by Natoco Co., Ltd.) as a (meth)acrylate oligomer, 30 wt % of 1,6-hexanediol diacrylate (HDDA, manufactured by Osaka Organic Chemical Industry Ltd.) as a monomer for dilution, 0.1 wt % of BYK-UV3500 (manufactured by BYK Japan KK) as a leveling agent, and 3 wt % of Irgacure184 (manufactured by BASF) as a photopolymerization initiator was applied onto the fine silver wiring pattern that was the conductive portion of the film A produced above by screen printing, thereby forming a coated film. Next, the coated film was exposed using a D valve manufactured by Fusion Co., Ltd. at an irradiation intensity of 160 mW/cm² so as to obtain an integrated illuminance of 1,000 mJ/cm², a transparent insulation layer that was a 10 μm-thick cured film was formed, and a conductive sheet for a touch sensor was manufactured.

<<Measurement of Individual Physical Properties>>

<Measurement of Indentation Hardness (Indentation Hardness)>

An indentation hardness of the transparent insulation layer was measured according to the following order.

The indentation hardness of the transparent insulation layer was measured using a microhardness tester (PICODENT) HM200 and a Berkovich terminal under measurement conditions of 1 mN/10 sec, a creep of five seconds, and a maximum indentation intensity of 0.35 μm.

<Measurement of Modulus of Elasticity>

A modulus of elasticity of the transparent insulation layer was measured according to the following order.

An indentation modulus of elasticity of the transparent insulation layer was measured using a microhardness tester (PICODENT) HM200 and a Berkovich terminal under a measurement condition of 0.1 mN/10 sec. Meanwhile, the indentation modulus of elasticity was measured in an environment of a temperature of 85° C. and a relative humidity of 85%.

<Measurement of Linear Expansion Coefficient>

A linear expansion coefficient of the transparent insulation layer was measured according to the following order.

The linear expansion coefficient of the transparent insulation layer was computed using the following two expressions by measuring a curl value (the curvature radius of a curl) in the case of applying a temperature to the transparent insulation layer formed on the PET film (40 μm).

(linear expansion coefficient of transparent insulation layer−linear expansion coefficient of PET)×temperature difference=distortion of measurement specimen Expression 1:

distortion of measurement specimen={(modulus of elasticity of PET×(thickness of PET)²}/{3×(1−Poisson's ratio of PET)×modulus of elasticity of transparent insulation layer×curvature radius of curl} Expression 2:

<<Evaluation>>

A variety of evaluations were carried out on the obtained conductive sheet for a touch sensor.

<Crack Evaluation>

A bending test was carried out using the conductive sheet for a touch sensor according to the following order, and the presence or absence of the generation of cracks in the transparent insulation layer was observed using an optical microscope.

In the bending test, a treatment of bending the conductive sheet for a touch sensor that was a sample by uniting the conductive sheet for a touch sensor with a ϕ1 mm piano wire and then returning the conductive sheet for a touch sensor was carried out 20 times. During the treatment, the conductive sheet for a touch sensor was bent with a surface on which the fine metal wires to be observed were present facing outwards.

<Evaluation of Fine Metal Wires in High-Temperature and High-Humidity Environment>

After the conductive sheet for a touch sensor was bent in ϕ2 mm (twice), the bent sample was stored in an environment of a temperature of 85° C. and a relative humidity of 85% for three days, and then the number of fissures in the 20 fine metal wires and the number of broken fine metal wires were evaluated.

Meanwhile, fissuring was evaluated by observing the fine metal wires using an optical microscope.

In addition, regarding breakage, a resistance of a fine metal wire was evaluated as being broken in a case in which a resistance value of the fine metal wire reached 1 MΩ or more in the case of being evaluated using a digital multimeter 34410A (manufactured by Agilent).

### Examples 2 to 11 and Comparative Examples 1 to 51

Conductive sheets for a touch sensor of Examples 2 to 11 and Comparative Examples 1 to 5 were produced using the same method as in Example 1 except for the fact that the composition or formulation of the conductive portion material or the composition for forming the transparent insulation layer were changed as shown in Tables 1 to 3 and evaluated in the same manner. The results are shown in Tables 1 to 3.

Hereinafter, a variety of materials used in Examples 1 to 11 and Comparative Examples 1 to 5 will be described.

(Polyfunctional Compound)

“PETA”: Pentaerythritol (tri/tetra)acrylate (trade name: KAYARAD PET-30, manufactured by Nippon Kayaku Co., Ltd.)

“DPHA”: Dipentaerythritol hexaacylate (trade name: KAYARAD DPHA, manufactured by Nippon Kayaku Co., Ltd.)

((Meth)Acrylate Compound)

“NATOCO UV SELF-HEALING”: Urethane acrylate compound (manufactured by Natoco Co. Ltd.)

“EXP DX-40”: Urethane acrylate compound (manufactured by DIC Corporation)

“AH-600”: Urethane acrylate compound (manufactured by Kyoei Kagaku Kogyo)

“UA-306H”: Urethane acrylate compound (manufactured by Kyoei Kagaku Kogyo)

“UA-306I”: Urethane acrylate compound (manufactured by Kyoei Kagaku Kogyo)

(Monomer for Dilution)

“HDDA”: 1,6-Hexanediol diacrylate (manufactured by Osaka Organic Chemical Industry Ltd.)

“IBXA”: Isobornyl acrylate (manufactured by Osaka Organic Chemical Industry Ltd.)

(Leveling Agent)

“BYK-UV3500”: (manufactured by BYK Japan KK)

(Photopolymerization Initiator)

“Irgacure184”: (manufactured by BASF)

(Composition for Forming Transparent Insulation Layer)

“Novec”: Insulation coating agent manufactured by 3M

(Conductive Portion Materials)

As the conductive portion materials, materials described below were used.
“Ag pattern”: A Ag pattern was as described in detail in the conductive sheet for a touch sensor of Example 1.

“Cu Pattern”:

First, a 5 nm-thick Ni layer was formed on a polyethylene terephthalate (PET) film using a sputtering method, and then a 2 μm-thick Cu flat film was formed thereon by depositing copper using a vacuum deposition method in which resistance heating was carried out. Next, the same pattern as the fine metal wiring pattern produced in Example 1 was provided using an ordinary lithography method, thereby producing a film having a conductive portion made of a Cu pattern on a base material.

“Ag Nanowire”:

A Ag nanowire was produced on a polyethylene terephthalate (PET) film according to the method described in JP2009-215594A, and a 1 μm-thick coated film was formed. Next, the same pattern as the fine metal wiring pattern produced in Example 1 was provided using an ordinary lithography method, thereby producing a film having a conductive portion made of a Ag wire on a base material.

TABLE 1

| | | Example 1 | | Example 2 | | Example 3 | |
|---|---|---|---|---|---|---|---|
| Conductive portion material | | Ag pattern | | Cu pattern | | Ag nanowire | |
| Composition | Polyfunctional | PETA | 30 | PETA | 30 | PETA | 30 |
| for forming | compound (% by | | | | | | |
| transparent | mass) | | | | | | |
| insulation | (Meth)acrylate | NATOCO UV | 36.9 | NATOCO UV | 36.9 | NATOCO UV | 36.9 |
| layer | compound (% by | SELF-HEALING | | SELF-HEALING | | SELF-HEALING | |
| (coating | mass) | | | | | | |
| fluid) | Dilution monomer | HDDA | 30 | HDDA | 30 | HDDA | 30 |
| | (% by mass) | | | | | | |
| | Leveling agent (% | BYK-UV3500 | 0.1 | BYK-UV3500 | 0.1 | BYK-UV3500 | 0.1 |
| | by mass) | | | | | | |
| | Photopolymerization | Irgacure184 | 3 | Irgacure184 | 3 | Irgacure184 | 3 |
| | initiator (% by | | | | | | |
| | mass) | | | | | | |

| | | | | |
|---|---|---|---|---|
| Transparent | Indentation hardness | 120 | 120 | 120 |
| insulation | (MPa) | | | |
| layer | | | | |
| | Modulus of | 3.2 × 10⁶ | 3.2 × 10⁶ | 3.2 × 10⁶ |
| | elasticity (85° C. 85 | | | |
| | RH %) (Pa) | | | |
| | Linear expansion | 140 | 140 | 140 |
| | coefficient (ppm/° C.) | | | |
| | Presence and | Present | Present | Present |
| | absence of | | | |
| | crosslinking | | | |
| | structure | | | |
| Evaluation | Fissuring of fine | 20 | 18 | 19 |
| result | metal wires (number | | | |
| | of OK/20 fine metal | | | |
| | wires) | | | |
| | Breakage of fine | 20 | 20 | 20 |
| | metal wires (number | | | |
| | of OK/20 fine metal | | | |
| | wires) | | | |
| | Crack evaluation of | None | None | None |
| | transparent | | | |
| | insulation layer | | | |

| | Example 4 | Example 5 | Example 6 |
|---|---|---|---|
| Conductive portion material | Ag pattern | Ag pattern | Ag pattern |

| | | | | | | | |
|---|---|---|---|---|---|---|---|
| Composition | Polyfunctional | PETA | 30 | PETA | 30 | PETA | 30 |
| for forming | compound (% by | | | | | | |
| transparent | mass) | | | | | | |
| insulation | (Meth)acrylate | EXP DX-40 | 36.9 | NATOCO UV | 36.9 | NATOCO UV | 36.9 |
| layer | compound (% by | | | SELF-HEALING | | SELF-HEALING | |
| (coating | mass) | | | | | | |
| fluid) | Dilution monomer | HDDA | 30 | HDDA | 30 | HDDA | 30 |
| | (% by mass) | | | | | | |
| | Leveling agent (% | BYK-UV3500 | 0.1 | BYK-UV3500 | 0.1 | BYK-UV3500 | 0.1 |
| | by mass) | | | | | | |
| | Photopolymerization | Irgacure184 | 3 | Irgacure184 | 3 | Irgacure184 | 3 |
| | initiator (% by | | | | | | |
| | mass) | | | | | | |

| | | | | |
|---|---|---|---|---|
| Transparent | Indentation hardness | 100 | 180 | 100 |
| insulation | (MPa) | | | |
| layer | | | | |
| | Modulus of | 2.4 × 10⁶ | 4.8 × 10⁶ | 2.4 × 10⁶ |
| | elasticity (85° C. 85 | | | |
| | RH %) (Pa) | | | |
| | Linear expansion | 140 | 160 | 150 |
| | coefficient (ppm/° C.) | | | |
| | Presence and | Present | Present | Present |
| | absence of | | | |
| | crosslinking | | | |
| | structure | | | |
| Evaluation | Fissuring of fine | 20 | 16 | 19 |
| result | metal wires (number | | | |
| | of OK/20 fine metal | | | |
| | wires) | | | |
| | Breakage of fine | 20 | 20 | 20 |
| | metal wires (number | | | |
| | of OK/20 fine metal | | | |
| | wires) | | | |
| | Crack evaluation of | None | None | None |
| | transparent | | | |
| | insulation layer | | | |

TABLE 2

| | | Example 7 | | Example 8 | | Example 9 | | Example 10 | | Example 11 | |
|---|---|---|---|---|---|---|---|---|---|---|---|
| Conductive portion material | | Ag pattern | | Ag pattern | | Ag pattern | | Ag pattern | | Ag pattern | |
| Composition | Polyfunctional | PETA | 45 | PETA | 30 | PETA | 30 | PETA | 30 | — | — |
| for forming | compound | | | | | | | | | | |
| transparent | (% by mass) | | | | | | | | | | |
| insulation | (Meth)acrylate | NATOCO UV | 51.9 | NATOCO UV | 37 | AH-600 | 36.9 | AH-306H | 36.9 | NATOCO UV | 66.9 |
| layer | compound | SELF- | | SELF- | | | | | | SELF- | |
| (coating | (% by mass) | HEALING | | HEALING | | | | | | HEALING | |
| fluid) | Dilution monomer | — | 0 | HDDA | 30 | HDDA | 30 | HDDA | 30 | IBXA | 30 |
| | (% by mass) | | | | | | | | | | |
| | Leveling agent | BYK- | 0.1 | — | — | BYK- | 0.1 | BYK- | 0.1 | BYK- | 0.1 |
| | (% by mass) | UV3500 | | | | UV3500 | | UV3500 | | UV3500 | |
| | Photopolymerization | Irgacure184 | 3 | Irgacure184 | 3 | Irgacure184 | 3 | Irgacure184 | 3 | Irgacure184 | 3 |
| | initiator | | | | | | | | | | |
| | (% by mass) | | | | | | | | | | |

| | | | | | | |
|---|---|---|---|---|---|---|
| Transparent | Indentation hardness | 140 | 120 | 130 | 150 | 10 |
| insulation | (MPa) | | | | | |
| layer | Modulus of | 2.4 × 10⁶ | 3.2 × 10⁶ | 4.5 × 10⁶ | 5.6 × 10⁶ | 1.2 × 10⁶ |
| | elasticity | | | | | |
| | (85° C. 85 RH %) | | | | | |
| | (Pa) | | | | | |
| | Linear expansion | 170 | 140 | 120 | 110 | 210 |
| | coefficient | | | | | |
| | (ppm/° C.) | | | | | |
| | Presence and | Present | Present | Present | Present | Present |
| | absence of | | | | | |
| | crosslinking | | | | | |
| | structure | | | | | |
| Evaluation | Fissuring of | 20 | 20 | 20 | 20 | 15 |
| result | fine metal | | | | | |
| | wires (number | | | | | |
| | of OK/20 fine | | | | | |
| | metal wires) | | | | | |
| | Breakage of | 20 | 20 | 20 | 20 | 14 |
| | fine metal | | | | | |
| | wires (number | | | | | |
| | of OK/20 fine | | | | | |
| | metal wires) | | | | | |
| | Crack evaluation of | None | None | None | None | None |
| | transparent insulation | | | | | |
| | layer | | | | | |

TABLE 3

| | | Comparative | Comparative | | Comparative | Comparative | | Comparative | |
|---|---|---|---|---|---|---|---|---|---|
| | | Example 1 | Example 2 | | Example 3 | Example 4 | | Example 5 | |
| Conductive portion material | | Ag pattern | Ag pattern | | Ag pattern | Ag pattern | | Ag pattern | |
| Composition | Polyfunctional | Novec | PETA | 97 | No transparent | PETA | 90 | PETA | 90 |
| for forming | compound | | | | insolation layer | | | | |
| transparent | (% by mass) | | | | | | | | |
| insulation | (Meth)acrylate | | NATOCO UV | 0 | | NATOCO UV | 6.9 | UA-3061 | 6.9 |
| layer (coating | compound | | SELF-HEALING | | | SELF-HEALING | | | |
| fluid) | (% by mass) | | | | | | | | |
| | Dilution monomer | | HDDA | 0 | | — | — | — | — |
| | (% by mass) | | | | | | | | |
| | Leveling agent | | BYK-UV3500 | 0 | | BYK-UV3500 | 0.1 | BYK-UV3500 | 0.1 |
| | (% by mass) | | | | | | | | |
| | Photopolymerization | | Irgacure184 | 3 | | Irgacure184 | 3 | Irgacure184 | 3 |
| | initiator (% by mass) | | | | | | | | |

| | | | | | | |
|---|---|---|---|---|---|---|
| Transparent | Indentation hardness | 0.01 | 410 | — | 210 | 230 |
| insulation | (MPa) | | | | | |
| layer | Modulus of elasticity | Measurement | 9.8 × 10⁶ | — | 7.5 × 10⁶ | 8.7 × 10⁶ |
| | (85° C. 85 RH %) (Pa) | limit or less | | | | |
| | Linear expansion | Measurement | 125 | — | 135 | 130 |
| | coefficient | limit or less | | | | |
| | (ppm/° C.) | | | | | |
| | Presence and absence | Absent | Present | — | Present | Present |
| | of crossiniking | | | | | |
| | structure | | | | | |
| Evaluation | Fissuring of fine metal | 3 | 4 | 1 | 12 | 9 |
| result | wires (number of | | | | | |
| | OK/20 fine metal | | | | | |
| | wires) | | | | | |
| | Breakage of fine metal | 3 | 3 | 1 | 9 | 7 |
| | wires (number of | | | | | |
| | OK/20 fine metal | | | | | |
| | wires) | | | | | |
| | Crack evaluation of | None | Present | None | Present | Present |
| | transparent | | | | | |
| | insulation layer | | | | | |

From the results of Tables 1 to 3, it was confirmed that the touch panel conductive sheet of the embodiment of the present invention is capable of obtaining a desired effect.

Meanwhile, from comparison among Examples 1 to 3, it was confirmed that, in a case in which the fine metal wire is a fine silver wire, the effects of the present invention are superior.

In addition, from the results of Example 5, it was confirmed that, in a case in which the indentation hardness of the transparent insulation layer is 150 MPa or less, the effects of the present invention are superior.

From the results of Example 11, it was confirmed that, in a case in which the modulus of elasticity of the transparent insulation layer at a temperature of 85° C. and a relative humidity of 85% is 1.5×10⁶ Pa or more, the effects of the present invention are superior.

On the other hand, in Comparative Example 1 in which the transparent insulation layer not having a crosslinking structure was used, Comparative Examples 2, 4, and 5 in which the indentation hardness of the transparent insulation layer was outside the predetermined range, and Comparative Example 3 in which the transparent insulation layer was not used, a desired effect could not be obtained.

### EXPLANATION OF REFERENCES

10, 100: conductive sheet for touch sensor
12: base material
14: fine metal wire
16: conductive portion
18: transparent insulation layer
20: opening portion
24: first detection electrode
26: first drawing wire
28: second detection electrode
30: second drawing wire
40: first transparent insulation layer
42: second transparent insulation layer
50: main body portion
52: bending portion
60: electrostatic capacitance-type touch panel
62: protective substrate
64: pressure-sensitive adhesive sheet
66: electrostatic capacitance-type touch sensor
68: display device

What is claimed is:

1. A conductive sheet for a touch sensor comprising:
a base material;
a conductive portion that is disposed on the base material and is made of a fine metal wire; and
a transparent insulation layer disposed on the conductive portion,
wherein the transparent insulation layer includes a crosslinking structure, and
an indentation hardness of the transparent insulation layer is 200 MPa or less.

2. The conductive sheet for a touch sensor according to claim 1,
wherein a modulus of elasticity of the transparent insulation layer at 50° C. to 90° C. is 1×10⁵ Pa or more.

3. The conductive sheet for a touch sensor according to claim 1,
wherein a modulus of elasticity of the transparent insulation layer at a temperature of 85° C. and a relative humidity of 85% is 1×10⁵ Pa or more.

4. The conductive sheet for a touch sensor according to claim 1,
wherein a difference between a linear expansion coefficient of the transparent insulation layer and a linear expansion coefficient of the base material is 300 ppm/° C. or less.

5. The conductive sheet for a touch sensor according to claim 2,
wherein a difference between a linear expansion coefficient of the transparent insulation layer and a linear expansion coefficient of the base material is 300 ppm/° C. or less.

6. The conductive sheet for a touch sensor according to claim 3,
wherein a difference between a linear expansion coefficient of the transparent insulation layer and a linear expansion coefficient of the base material is 300 ppm/° C. or less.

7. The conductive sheet for a touch sensor according to claim 1,
wherein the conductive portions are disposed on both surfaces of the base material, and
the conductive portions include a mesh pattern made of a fine silver wire.

8. The conductive sheet for a touch sensor according to claim 1, further comprising:
a main body portion; and
a bending portion that is extended from the main body portion and is bendable.

9. The conductive sheet for a touch sensor according to claim 2, further comprising:
a main body portion; and
a bending portion that is extended from the main body portion and is bendable.

10. The conductive sheet for a touch sensor according to claim 3, further comprising:
a main body portion; and
a bending portion that is extended from the main body portion and is bendable.

11. The conductive sheet for a touch sensor according to claim 4, further comprising:
a main body portion; and
a bending portion that is extended from the main body portion and is bendable.

12. The conductive sheet for a touch sensor according to claim 5, further comprising:
a main body portion; and
a bending portion that is extended from the main body portion and is bendable.

13. The conductive sheet for a touch sensor according to claim 6, further comprising:
a main body portion; and
a bending portion that is extended from the main body portion and is bendable.

14. The conductive sheet for a touch sensor according to claim 7, further comprising:
a main body portion; and
a bending portion that is extended from the main body portion and is bendable.

15. The conductive sheet for a touch sensor according to claim 8, further comprising:
a curved portion that is formed by bending the bending portion.

16. A laminate for a touch sensor comprising, in order:
the conductive sheet for a touch sensor according to claim 1;
a pressure-sensitive adhesive sheet; and
a peeling sheet.

17. A touch sensor comprising:
the conductive sheet for a touch sensor according to claim 1.

18. A touch panel comprising:
the touch sensor according to claim 17.
